(19) United States
(12) Patent Application Publication
(10) Pub. No.: US 2006/0215366 A1
(43) Pub. Date: Sep. 28, 2006

(54) Apparatus, system, and method for removing excess heat from a component

(76) Inventors: Vinod Kamath, Raleigh, NC (US); Albert Vincent Makley, Raleigh, NC (US); Jason Aaron Matteson, Raleigh, NC (US)

Correspondence Address: KUNZLER & ASSOCIATES, 8 EAST BROADWAY, SUITE 600, SALT LAKE CITY, UT, 84111, US

(21) Appl. No.: 11/088,661

(22) Filed: Mar. 24, 2005

(51) Int. Cl. H05K 7/20

(52) U.S. Cl. 361/700

(57) ABSTRACT

An apparatus, system, and method are disclosed for removing excess heat from a component. A heat sink is included and located in an area in a computer with excess cooling capacity. A heat pipe is included and is connected to the heat sink and extends to a heat sensitive component located in the computer. A heat conducting compliance pad is connected to the heat sensitive component. A heat conducting metallic connector is connected to the heat pipe and to the compliance pad.

### BACKGROUND OF THE INVENTION

1. Field of the Invention

This invention relates to removing excess heat from a component and more particularly relates to removing excess heat from a computer component by conducting heat to an area with excess cooling capacity.

2. Description of the Related Art

In computers with limited space requirements, cooling of components is a critical part of the design. Component cooling is balanced with other design constraints such as space requirements and connectivity requirements. As a result, a heat sensitive component, such as a hard drive or processor, may be located such that cooling of the component is compromised. A heat sensitive component may be, but is not limited to, any component that would benefit by removing heat beyond the heat removed through typical convection or forced air cooling.

A heat sensitive component with inadequate cooling may run less efficiently. A heat sensitive component with inadequate cooling may also fail prematurely. Premature component failure and inefficient operation reduce the reliability and marketability of a computer and may result in reduced profits for the computer seller.

Typical methods of cooling using forced air or convection may not adequately cool heat sensitive components. Forced air cooling using directional channels or vanes may not be effective due to space constraints or cost. Adding more cooling through larger fans or additional fans may not be an effective solution due to long-term energy costs, reduced reliability, noise considerations, or the like.

Adding a heat sink to a heat sensitive component may not be possible due to space constraints. Adding a heat sink to a heat sensitive component also may not be effective if the heat sensitive component is located where cooling capacity is not adequate to make the addition of a heat sink effective.

The above mentioned problems associated with cooling a heat sensitive component are compounded in computers or other electronic equipment with extreme space constraints such as rack-mounted blade servers, lap-top computers, and the like. In addition, low energy use constraints in computers such as lap-top computers makes solving cooling problems for heat sensitive components through increased fan size or additional fans an unattractive solution.

From the foregoing discussion, it should be apparent that a need exists for an apparatus, system, and method to conduct heat from a heat sensitive component to an area in a computer with excess cooling capacity. Beneficially, such an apparatus, system, and method would conduct heat from a heat sensitive component to an area in a computer with excess cooling capacity efficiently, reliably and without increasing energy needs.

### SUMMARY OF THE INVENTION

The present invention has been developed in response to the present state of the art, and in particular, in response to the problems and needs in the art that have not yet been fully solved by currently available ways to remove heat from a component. Accordingly, the present invention has been developed to provide an apparatus, system, and method for removing excess heat from a component that overcome many or all of the above-discussed shortcomings in the art.

The apparatus to remove excess heat from a component is provided with a heat sink located in an area in a computer with excess cooling capacity, a heat pipe connected to the heat sink and extending to a heat sensitive component located in the computer, a heat conducting compliance pad connected to the heat sensitive component, and a heat conducting metallic connector connected to the heat pipe and to the compliance pad. In one embodiment, the heat sensitive component is a computer hard drive. In another embodiment, more than one hard drive is included and each hard drive is connected to a compliance pad that is connected to a metallic connector connected to the heat pipe. In yet another embodiment, the heat sink extends the length of the heat pipe. In an alternate embodiment, the heat sink comprises the heat conducting metallic connector.

In one embodiment, the location in the computer with excess cooling capacity has excess forced air cooling capacity. In another embodiment, the location in the computer with excess cooling capacity has a lower ambient temperature than the location of the heat sensitive component. The heat pipe, in one embodiment, is a one millimeter copper heat pipe. The one millimeter copper heat pipe, in another embodiment, is flattened to an oval shape to reduce the heat pipe's height. The heat pipe may contain water in a vapor state or a liquid state. The heat pipe may contain another substance.

The compliance pad, in one embodiment, self adjusts to fill the space between the heat sensitive component and the heat conducting metallic connector by application of a positive pressure between the heat conducting metallic connector and the heat sensitive component. In another embodiment, the compliance pad is connected to the heat sensitive component or to the heat conducting metallic connector by the tackiness of the compliance pad. In an alternate embodiment, the compliance pad is connected to the heat sensitive component or to the heat conducting metallic connector by a thermally conductive adhesive. In yet another embodiment, the computer is a blade server.

A system of the present invention is also presented to remove excess heat from a component. The system may be embodied by a computer connected to the computer network. The computer includes a heat sink located in an area in the computer with excess cooling capacity, a heat pipe connected to the heat sink and extending to a heat sensitive component located in the computer, and a heat conducting compliance pad connected to the heat pipe.

In particular, in one embodiment, the heat sensitive component is a hard drive. In another embodiment, the computer includes more than one hard drive where each hard drive is in contact with a compliance pad fastened to the hard drive with a connector that is connected to the heat pipe. In an alternate embodiment, the heat sink is aluminum and extends the length of the heat pipe, the heat sink connects to the heat pipe, and the compliance pad connects to the heat sink. In another embodiment, the heat pipe is a one millimeter heat pipe flattened to an oval shape to reduce the heat pipe's height.

An alternate apparatus to remove excess heat from a component is presented and includes a heat sink comprising a flat aluminum plate extending from a heat sensitive component located in the computer to an area in the computer with excess cooling capacity, a heat pipe connected along the length of the heat sink, and a heat conducting compliance pad connected to the heat sensitive component and to the heat sink. In one example, the heat sensitive component includes at least one computer hard drive where each hard drive is connected to a compliance pad that is connected to the heat sink. In another example, the heat pipe is a one millimeter heat pipe flattened to an oval shape to reduce the heat pipe's height and containing water in the form of a gas or liquid. In another embodiment, the compliance pad self adjusts to fill the space between the heat sensitive component and the heat sink by application of a positive pressure applied between the heat sink and the heat sensitive component.

A method of the present invention is also presented for removing excess heat from a component. The method in the disclosed embodiments substantially includes the steps necessary to carry out the functions presented above with respect to the operation of the described apparatus and system. In one embodiment, the method includes locating a heat sink in an area in a computer with excess cooling capacity, connecting a heat pipe to the heat sink and extending the heat sink to a heat sensitive component in the computer, connecting a heat conducting compliance pad to the heat sensitive component, and connecting a heat conducting metallic connector to the heat pipe and to the compliance pad. In one embodiment, the heat sensitive component includes one or more hard drives and further includes connecting a compliance pad to each hard drive, connecting a heat conducting metallic connector to each compliance pad, and connecting each heat conducting metallic connector to the heat pipe. In another embodiment, the heat sink is an aluminum plate extending the length of the heat pipe and comprises the heat conducting metallic connector. In yet another embodiment, the heat pipe is a one millimeter heat pipe flattened to an oval shape to reduce the heat pipe's height.

A method is also presented for deploying computing infrastructure, where the computing system includes an apparatus for removing excess heat from a component. The apparatus includes a heat sink located in an area in a computer with excess cooling capacity, a heat pipe connected to the heat sink and extending to a heat sensitive component located in the computer, a heat conducting compliance pad connected to the heat sensitive component, and a heat conducting metallic connector connected to the heat pipe and to the compliance pad. In one embodiment, the heat sensitive component is at least one hard drive.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

These features and advantages of the present invention will become more fully apparent from the following description and appended claims, or may be learned by the practice of the invention as set forth hereinafter.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1a is a side view of a schematic block diagram illustrating a typical circuit board with components;

FIG. 1b is a top view of a schematic block diagram illustrating a typical circuit board with components;

FIG. 2a is a side view of a schematic block diagram illustrating one embodiment of an apparatus for removing excess heat from a component in accordance with the present invention;

FIG. 2b is a top view of a schematic block diagram illustrating one embodiment of an apparatus for removing excess heat from a component in accordance with the present invention;

FIG. 3a is a side view of a heat sensitive component and connection to an apparatus for removing excess heat from the component in accordance with the present invention;

FIG. 3b is an end view of a heat sensitive component and connection to an apparatus for removing excess heat from the component in accordance with the present invention;

FIG. 4a is a side view of a schematic block diagram illustrating an alternate embodiment of an apparatus for removing excess heat from a component in accordance with the present invention;

FIG. 4b is a top view of a schematic block diagram illustrating an alternate embodiment of an apparatus for removing excess heat from a component in accordance with the present invention;

FIG. 5 in an end view of a heat sink and heat pipe that are part of an apparatus for removing excess heat from a component in accordance with the present invention.

### DETAILED DESCRIPTION OF THE INVENTION

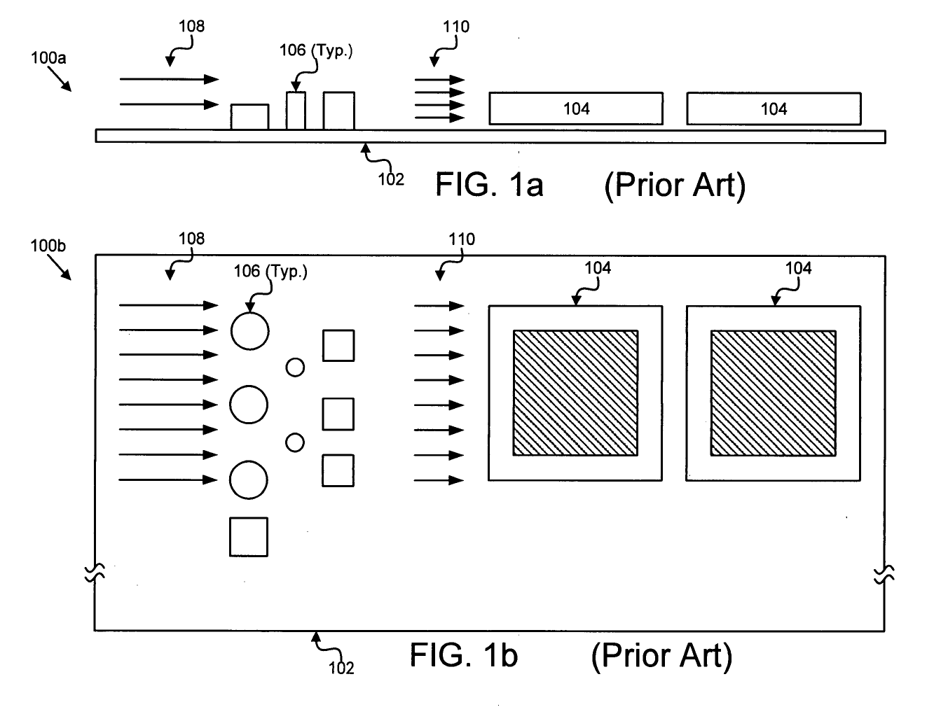

FIG. 1a is a side view of a schematic block diagram 100a illustrating a typical circuit board with components. FIG. 1b is a top view of the schematic block diagram 100b illustrating the circuit board with components. The diagrams 100a, 100b depict a typical circuit board 102 that may be part of a server, a laptop computer, a workstation, or other electronic device. The circuit board 102 includes one or more heat sensitive components 104. In one embodiment, the heat sensitive component 104 is a hard drive. In another embodiment, the heat sensitive component 104 is a processor. In yet another embodiment, the heat sensitive component 104 is a random access memory (“RAM”). One skilled in the art will recognize other heat sensitive components where removal of excess heat is beneficial.

The circuit board 102 includes other components 106. The components 106 may be resistors, capacitors, integrated circuits, processors, memory, or the like. The components 106 are situated on the circuit board 102 to have cooling by means of air flow 108 or air circulation. The air flow 108 may be caused by forced air cooling using a fan, convection cooling, or other typical computer cooling method. The components 106 are situated with respect to the heat sensitive components 104 so that the heat sensitive components 104 have less air flow 110 or cooling capacity than the air flow 108 or cooling for the components 106.

In one embodiment, the circuit board 102 is part of a blade server with limited space requirements. In such a blade server, cooling of a heat sensitive component 104 may be more difficult than for other components 106 due to space constraints and layout requirements. Increased cooling to the heat sensitive components 104 is desirable for increased performance, increased life, or increased reliability of the heat sensitive component 104. Increased cooling by means of increased air flow 110 to the heat sensitive component 104 may be difficult due to space constraints, energy constraints, or noise constraints. For example, increasing the size of a fan used for cooling may increase energy costs beyond desired or required limits or may increase noise levels beyond acceptable bounds. In another example, space constraints may hinder the use of vanes or ducts to direct more air flow 108 to the heat sensitive component 104. In other embodiments, the circuit board 102 is part of a laptop, a server, a workstation, a desktop computer, digital video disc (“DVD”) player, or other electronic device.

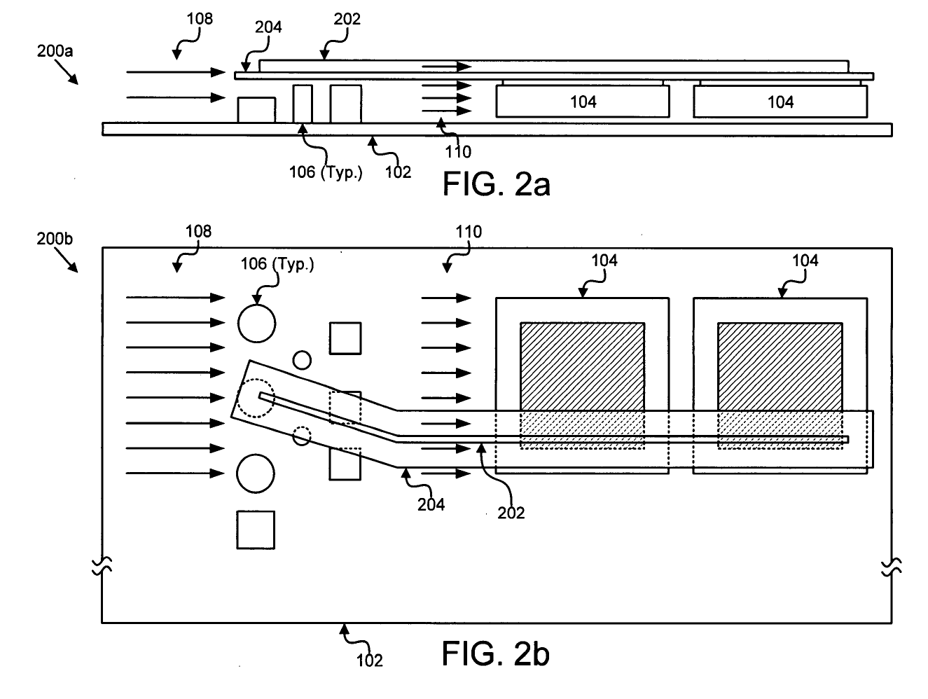

FIG. 2a is a side view of a schematic block diagram 200a and FIG. 2b is a top view of a schematic block diagram 200b, both illustrating one embodiment of an apparatus for removing excess heat from a component in accordance with the present invention. The diagrams 200a, 200b include the circuit board 102, heat sensitive components 104, other components 106, air flow 108 to the components 106, and limited air flow 110 to the heat sensitive components 104 as described above in relation to FIGS. 1a and 1b.

The diagrams 200a, 200b also include a heat pipe 202 and a heat sink 204. The heat pipe 202 is a heat transfer device capable of transferring a large amount of heat from one end of the heat pipe 202 to the other end. The heat pipe 202 is an isothermal device. The heat pipe 202 can be viewed as a thermal conductor with a typical capacity of 5,000 to 10,000 watts per meter Kelvin. Typical heat sink devices have a capacity much lower than for a heat pipe 202. In one embodiment, the heat pipe 202 is a hollow copper tube sealed at both ends. The copper tube is filled with a liquid or vapor and sealed at a specific atmospheric pressure and temperature. The heat pipe 202 is lined with a material to wick liquid from one end of the heat pipe 202 to the other using capillary action.

A typical heat pipe 202 is designed so that when it is placed in contact with a device with an elevated temperature, heat is transferred from the device to the heat pipe 202. The heat is then transferred through the walls of the heat pipe 202 at the end in contact with the device, or hot end, of the heat pipe 202. The heat entering the heat pipe 202 at this hot end then causes the liquid to transform to a vapor state and migrate to the other end, or cool end, of the heat pipe 202 by way of pressure differential. As the vapor moves along the heat pipe 202 towards the cool end, heat is transferred to through the walls of the heat pipe 202 and radiated causing the vapor to cool and transform back to a liquid state. The liquid then is drawn back to the hot end of the heat pipe 202 via capillary action. The process then repeats. The process of extracting heat from a device into a heat pipe 202 and moving the heat to the other end of the heat pipe 202 is a closed loop process. A heat pipe 202 is typically much more efficient at moving heat from one place to another than a typical heat sink.

The heat pipe 202 extends from the heat sensitive component 104 to an area with excess cooling capacity, with reduced ambient temperature, or with excess air flow 108. The heat pipe 202 may extend past components 106 that may block air flow 108 resulting in reduced air flow 110 at the heat sensitive component 104.

The heat pipe 202 is attached to a heat sink 204. In the depicted embodiment of the diagrams 200a, 200b, in FIGS. 2a and 2b the heat sink 204 is shown as a plate that extends the length of the heat pipe 202. In one embodiment, the heat sink 204 is a flat aluminum plate. In another embodiment, the heat sink 204 is a copper plate. In another embodiment, the heat sink 204 has fins. One skilled in the art will recognize other embodiments of a heat sink 204 configured to remove excess heat from a component.

In one embodiment, a heat pipe 202 removes excess heat from a heat sensitive component 104 and no heat sink 204 is present. The heat sink 204 may be included to reduce cost by reducing the required size of the heat pipe 202. The size of the heat sink 204 may be traded against the size and cost of the heat pipe 202. In one embodiment, the heat pipe 202 is copper. In another embodiment, the heat pipe 202 is 3 millimeter in diameter. Another typical diameter for a heat pipe 202 is 6 millimeters. In yet another embodiment, the heat pipe 202 is a 3 millimeter heat pipe 202 that is flattened into an oval so the height is 1 millimeter. In one example, the heat pipe 202 includes water vapor. Other possible fluids in the heat pipe 202 include ammonia, ethanol, and toluene. One skilled in the art will recognize other liquids to include in a heat pipe 202 for removing excess heat from a component based on required thermodynamic conditions.

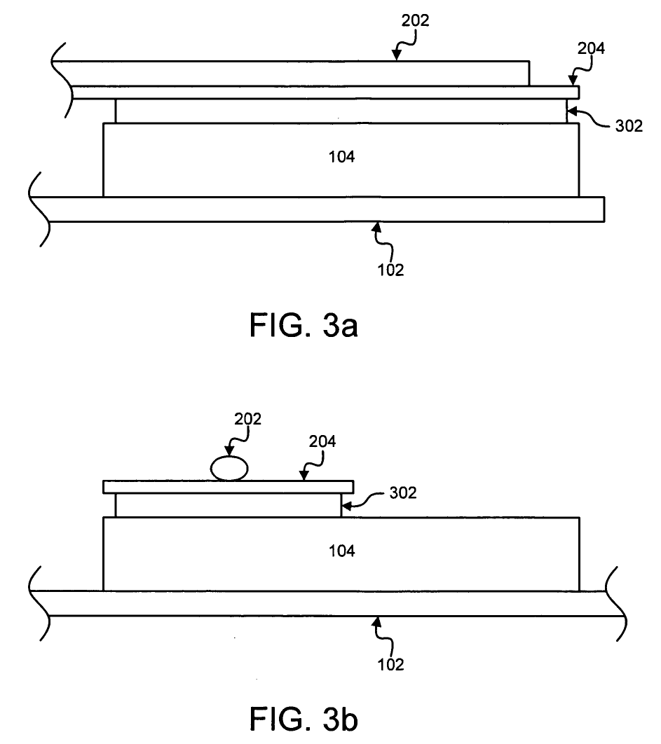

FIG. 3a is a side view of a schematic block diagram 300a and FIG. 3b is an end view of a schematic block diagram 300b of a heat sensitive component and connection to an apparatus for removing excess heat from the component in accordance with the present invention. The heat sensitive component 104 on the circuit board 102 is connected to a thermally conductive compliance pad 302. The compliance pad 302 functions to fill the gap between the heat sensitive component 104 and the heat sink 204 or heat pipe 202. The heat sensitive component 104 may include a mounting tolerance so that the top of the heat sensitive component 104 varies. The heat sink 204 or heat pipe 202 may also vary in position as well. The compliance pad 302 is a material that may vary in thickness to fill the gap and any voids between the heat sensitive component 302 and either the heat sink 204 or heat pipe 202. The thickness of the compliance pad 302 may vary and fill voids between the heat sensitive component 104 and the heat sink 204 or heat pipe 202 in response to pressure applied between the heat sensitive component 104 and heat sink 204 or heat pipe 202.

The compliance pad 302 may be sized as necessary to transmit a required amount of heat from the heat sensitive component 104 to the heat sink 204 or heat pipe 202. In one embodiment, the heat sink 204 is connected to the circuit board 102 or to the heat sensitive component 104 with tabs or hinge pins or both. As the heat sink 204 is connected, a positive pressure is applied to the compliance pad 302 such that the compliance pad 302 is compressed. As the compliance pad 302 is compressed, it may partially or fully fill gaps or voids between the heat sensitive component 104 and the heat sink 204. An amount of positive pressure is applied to the compliance pad 302 sufficient to enable the required amount of heat to flow from the heat sensitive component 104 to the heat sink 204 or heat pipe 202 but the applied pressure is lower than an amount that would damage the heat sensitive component 104, heat sink 204, heat pipe 202, or circuit board 102.

In one embodiment, the compliance pad 302 is connected to the heat sensitive component 104 or to the heat sink 204 using a thermally conductive adhesive. In another embodiment, the compliance pad 302 is connected to the heat sensitive component 104 or to the heat sink 204 or to both using the inherent tackiness of the surface of the compliance pad 302. One skilled in the art will recognize other embodiments of connecting the compliance pad 302 without affecting thermal conductivity so that the compliance pad 302 will remain in place.

In an alternate embodiment, the heat pipe 202 is connected to the compliance pad 202. Such an embodiment would not require a heat sink 204 but may require a larger heat pipe 202. One skilled in the art will recognize the tradeoffs between a design with a heat sink 204 between the compliance pad 302 and the heat pipe 202 and a design without a heat sink 204 between the compliance pad 302 and the heat pipe 202.

FIG. 3b is an end view of a heat sensitive component 104 and connection to an apparatus for removing excess heat from the component in accordance with the present invention. The heat sensitive component 104 is connected to a circuit board 102 and a compliance pad 302 which is connected to a heat sink 204, 302 which is connected to the heat pipe 202. In another embodiment, the heat sensitive component 104 is connected to a compliance pad 302 which is connected directly to the heat pipe 202. In one embodiment, the heat pipe 202 is an oval shape to reduce the height of the heat pipe 202 where the overall height of the apparatus is minimized. In another embodiment, the heat pipe 202 is round. One skilled in the art will recognize the trade off between heat pipe 202 size and height.

In one embodiment, the heat sink 204 only covers a portion of the heat sensitive component 104. In another embodiment, the heat sink 204 covers the entire heat sensitive component 104. One skilled in the art will recognize the amount of contact, location, and shape of a heat sink 204 to adequately transfer heat from the heat sensitive component 104 through a compliance pad 302 to the heat sink 204 and then to the heat pipe 202.

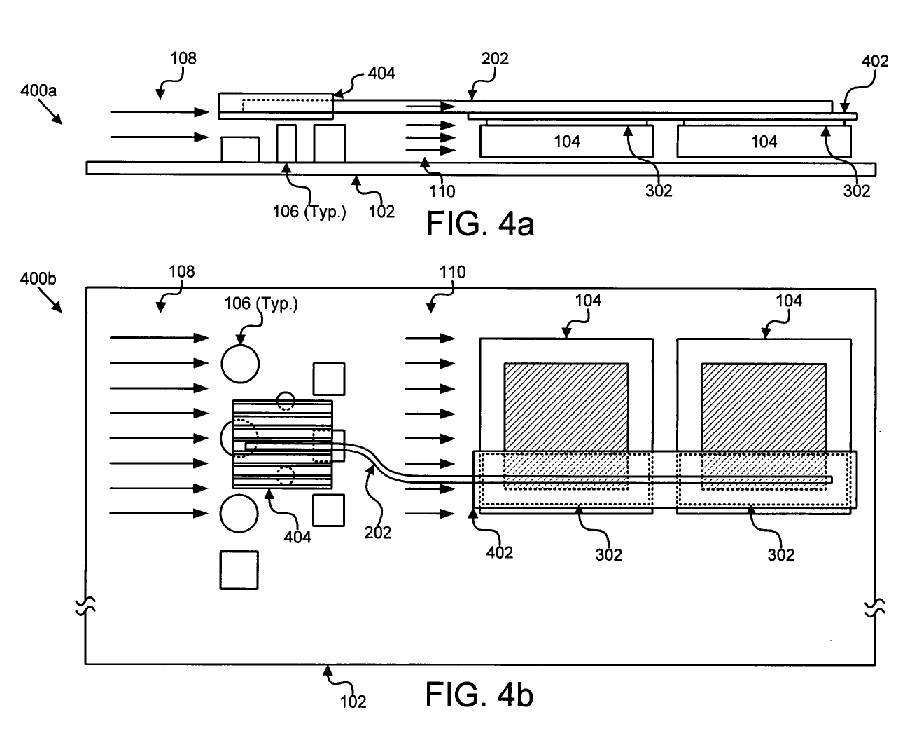

FIG. 4a is a top view of a schematic block diagram 400a and FIG. 4b is a side view of a schematic block diagram 400b illustrating an alternate embodiment of an apparatus for removing excess heat from a component in accordance with the present invention. The diagrams 400a, 400b include the circuit board 102, heat sensitive components 104, other components 106, air flow 108 to the components 106, and limited air flow 110 to the heat sensitive components 104 as described above in relation to FIGS. 1a and 1b. In the depicted embodiment, a heat conducting metallic connector 402 is connected to each compliance pad 302. In another embodiment, more than one heat conducting metallic connector 402 connects to each compliance pad 302 and each heat conducting metallic connector 402 connects to the heat pipe 202. In yet another embodiment, the compliance pad 302 is connected directly to the heat pipe 202. In one embodiment, the heat conducting metallic connector 402 is a heat sink.

In one embodiment, heat is transferred from the heat sensitive component 104 through each compliance pad 302 to the heat conducting metallic connector 402 and then to the heat pipe 202. In another embodiment, heat is transferred from the heat sensitive component 104 through the compliance pad 302 directly to the heat pipe 202. The heat pipe 202 extends to an area with extra cooling capacity or air flow 108.

In one embodiment, the heat pipe 202 is connected to and transfers heat to a heat sink 404 located in an area of airflow 108 that is not as limited as the limited airflow 110 to the heat sensitive component 104. In one embodiment, the air flow 108 has excess heat removing capacity. In another embodiment, the heat sink 404 is in an area where convection cooling is adequate to transfer a required amount of heat from the heat sink 404. In an alternate embodiment, the heat sink 404 is located outside the compartment that includes the heat sensitive component 104. In one embodiment, the heat sink 404 is located on the exterior of the electronic device or computer containing the heat sensitive component 104 and other components 106.

One skilled in the art will recognize other locations for a heat sink 404 connected to the heat pipe 202 and located so a required amount of heat is transferred from the heat sink 404. One skilled in the art may also trade off the size of the heat pipe 202 with the size and location of a heat conducting metallic connector 402 and a heat sink 404. In addition, one skilled in the art may trade off having a single heat sink 204 in the diagram 200 in FIG. 2 or one or more heat conducting metallic connectors 402 and a heat sink 404. In one embodiment, a heat pipe 202 is connected directly to one or more compliance pads 302 at one end and to a heat sink 404 at the other end of the heat pipe 202.

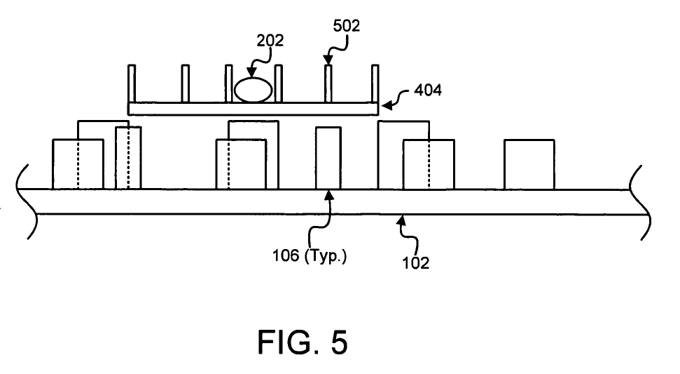

FIG. 5 is an end view of a heat sink 404 and heat pipe 202 that are part of an apparatus for removing excess heat from a component in accordance with the present invention. The heat sink 404, in one embodiment, includes fins 502. One skilled in the art will recognize space limitations, amount of heat to be removed, and air flow 108 or heat removal capacity required to design a heat sink 404 with or without fins 502. The fins 502 may be of any size or configuration required to transfer the requisite amount of heat.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the preceding description, numerous specific details are provided, such as examples of user selections, hardware configurations, heat sink configurations, etc., to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus to remove excess heat from a component, the apparatus: comprising:
a heat sink located in an area in a computer with excess cooling capacity;
a heat pipe connected to the heat sink and extending to a heat sensitive component located in the computer;
a heat conducting compliance pad connected to the heat sensitive component; and
a heat conducting metallic connector connected to the heat pipe and to the compliance pad.

2. The apparatus of claim 1, wherein the heat sensitive component is a computer hard drive.

3. The apparatus of claim 2, further comprising more than one hard drive and wherein each hard drive is connected to a compliance pad, and each compliance pad is connected to a metallic connector connected to the heat pipe.

4. The apparatus of claim 1, wherein the heat sink extends the length of the heat pipe.

5. The apparatus of claim 4, wherein the heat sink comprises the heat conducting metallic connector.

6. The apparatus of claim 1, wherein the location in the computer with excess cooling capacity has excess forced air cooling capacity.

7. The apparatus of claim 1, wherein the location in the computer with excess cooling capacity has a lower ambient temperature than the location of the heat sensitive component.

8. The apparatus of claim 1, wherein the heat pipe is a one millimeter copper heat pipe.

9. The apparatus of claim 8, wherein the one millimeter copper heat pipe is flattened to an oval shape to reduce the heat pipe's height.

10. The apparatus of claim 1, wherein the heat pipe contains water in a vapor state or liquid state.

11. The apparatus of claim 1, wherein the compliance pad self adjusts to fill the space between the heat sensitive component and the heat conducting metallic connector by application of a positive pressure applied between the heat conducting metallic connector and the heat sensitive component.

12. The apparatus of claim 1, wherein the compliance pad is connected to the heat sensitive component or to the heat conducting metallic connector by the tackiness of the compliance pad.

13. The apparatus of claim 1, wherein the compliance pad is connected to the heat sensitive component or to the heat conducting metallic connector by a thermally conductive adhesive.

14. The apparatus of claim 1, wherein the computer is a blade server.

15. A system to remove excess heat from a component, the system comprising:
a computer connected to a computer network wherein the computer comprises
a heat sink located in an area in the computer with excess cooling capacity;
a heat pipe connected to the heat sink and extending to a heat sensitive component located in the computer; and
a heat conducting compliance pad connected to the heat pipe.

16. The system of claim 15, wherein the heat sensitive component is a hard drive.

17. The system of claim 16, further comprising more than one hard drive, and wherein each hard drive is in contact with a compliance pad, and each compliance pad is fastened to the hard drive with a connector that is connected to the heat pipe.

18. The system of claim 15, wherein the heat sink is aluminum and extends the length of the heat pipe, the heat sink connects to the heat pipe, and the compliance pad connects to the heat sink.

19. The system of claim 15, wherein the heat pipe is a one millimeter heat pipe flattened to an oval shape to reduce the heat pipe's height.

20. An apparatus to remove excess heat from a component, the apparatus comprising:
a heat sink comprising a flat aluminum plate extending from a heat sensitive component located in the computer to an area in the computer with excess cooling capacity;
a heat pipe connected along the length of the heat sink; and
a heat conducting compliance pad connected to the heat sensitive component and to the heat sink.

21. The apparatus of claim 20, wherein the heat sensitive component comprises at least one computer hard drive, and wherein each hard drive is connected to a compliance pad, and each compliance pad is connected to the heat sink.

22. The apparatus of claim 21, wherein the heat pipe is a one millimeter heat pipe flattened to an oval shape to reduce the heat pipe's height and containing water in the form of a gas or liquid.

23. The apparatus of claim 22, wherein the compliance pad self adjusts to fill the space between the heat sensitive component and the heat sink by application of a positive pressure applied between the heat sink and the heat sensitive component.

24. A method for removing excess heat from a component, the method comprising:
locating a heat sink in an area in a computer with excess cooling capacity;
connecting a heat pipe to the heat sink and extending the heat sink to a heat sensitive component in the computer;
connecting a heat conducting compliance pad to the heat sensitive component; and
connecting a heat conducting metallic connector to the heat pipe and to the compliance pad.

25. The method of claim 24, wherein the heat sensitive component comprises one or more hard drives and further comprising connecting a compliance pad to each hard drive, connecting a heat conducting metallic connector to each compliance pad, and connecting each heat conducting metallic connector to the heat pipe.

26. The method of claim 24, wherein the heat sink is an aluminum plate extending the length of the heat pipe and comprises the heat conducting metallic connector.

27. The method of claim 24, wherein the heat pipe is a one millimeter heat pipe flattened to an oval shape to reduce the heat pipe's height.

28. An apparatus to remove excess heat from a component, the apparatus comprising:
means for locating a heat sink in an area in a computer with excess cooling capacity;
means for connecting a heat pipe to the heat sink and extending the heat sink to a heat sensitive component in the computer;
means for connecting a heat conducting compliance pad to the heat sensitive component; and
means for connecting a heat conducting metallic connector to the heat pipe and to the compliance pad.

29. A method for deploying computing infrastructure, wherein the computing system comprises an apparatus for removing excess heat from a component comprising:
a heat sink located in an area in a computer with excess cooling capacity;
a heat pipe connected to the heat sink and extending to a heat sensitive component located in the computer;
a heat conducting compliance pad connected to the heat sensitive component; and
a heat conducting metallic connector connected to the heat pipe and to the compliance pad.

30. The method for deploying computing infrastructure of claim 29, wherein the heat sensitive component is at least one hard drive.
